(19) United States
(12) Patent Application Publication
(10) Pub. No.: US 2023/0154903 A1
(43) Pub. Date: May 18, 2023

(54) LIGHT-EMITTING DIODE (LED) CHIP ASSEMBLY AND PREPRAING METHOD THEREOF, AND PREPARING METHOD OF DISPLAY PANEL

(71) Applicant: CHONGQING KONKA PHOTOELECTRIC TECHNOLOGY RESEARCH INSTITUTE CO, LTD., Chongqing (CN)

(72) Inventors: GuangChao DAI, Chongqing (CN); FeiFan MA, Chongqing (CN); ZiChuan WANG, Chongqing (CN); ShiXiong ZHAO, Chongqing (CN)

(21) Appl. No.: 17/977,096

(22) Filed: Oct. 31, 2022

Related U.S. Application Data
(63) Continuation of application No. PCT/CN2021/130962, filed on Nov. 16, 2021.

(51) Int. Cl. H01L 25/075; H01L 33/00; H01L 21/66

(52) U.S. Cl. CPC H01L 25/0753; H01L 33/005; H01L 22/22; H01L 2933/0066

(57) ABSTRACT

A light-emitting diode (LED) chip assembly and a preparing method thereof, and a preparing method of a display panel are provided. The LED chip assembly includes a patterned substrate, a patterned support layer, and multiple LED chips. The patterned substrate defines multiple through holes. The patterned support layer is disposed on a surface of the patterned substrate and attached to the patterned substrate. Each LED chip at least partially extends into each through hole. The each LED chip is partially embedded in the patterned support layer, and the each LED chip has a face surface away from the patterned support layer. The patterned support layer defines a hollow structure at a position opposite to a back surface of the each LED chip.

### CROSS-REFERENCE TO RELATED APPLICATIONS

This application is a continuation of International Application No. PCT/CN2021/130962, filed Nov. 16, 2021, the entire disclosure of which is incorporated herein by reference.

### TECHNICAL FIELD

This disclosure relates to the field of display, and in particular to a light-emitting diode (LED) chip assembly and a preparing method thereof, and a preparing method of a display panel.

### BACKGROUND

After a micro light-emitting diode (Micro-LED) is prepared on a wafer, the Micro-LED usually needs two or more transfers to be bonded to a drive backplane to realize preparation of a display panel. Due to a small size of the Micro-LED, mass transfer is needed, that is, a large number of chips are transferred to the drive backplane at one time. In some production scenarios, Micro-LEDs are required to be transferred up to 3×10⁶ Micro-LEDs per hour. At present, many manufacturers choose to transfer the Micro-LEDs to the drive backplane by micro-transfer-printing (μTP) technology and van der Waals force. However, a transfer yield and a transfer efficiency of the μTP technology are not ideal. Therefore, how to quickly transfer the Micro-LEDs to the drive backplane is an urgent problem to be solved at present.

### SUMMARY

In a first aspect, a LED chip assembly is provided in the present disclosure. The LED chip assembly includes a patterned substrate, a patterned support layer, and multiple LED chips. The patterned substrate defines multiple through holes. The patterned support layer is disposed on a surface of the patterned substrate and attached to the patterned substrate. Each LED chip at least partially extends into each through hole, the each LED chip is partially embedded in the patterned support layer, and the each LED chip has a face surface away from the patterned support layer. The patterned support layer defines a hollow structure which is at a position opposite to a back surface of the each LED chip and is for an operation body to extend into the hollow structure and touch the each LED chip, to apply a pressure to the each LED chip to make the each LED chip fall off the patterned support layer and out of the each through hole. When the each LED chip is fixed to a drive backplane, the face surface is a surface of the each LED chip facing the drive backplane and the back surface is a surface of the each LED chip away from the drive backplane.

In a second aspect, a preparing method of a LED chip assembly is further provided in the present disclosure. The preparing method includes the following. A carrier substrate with multiple LED chips and a temporary transfer substrate with multiple grooves are provided, the temporary transfer substrate includes a patterned substrate with multiple through holes and a temporary base plate which are laminated, and each groove is defined by each through hole. Each bonding pad is disposed on a face surface of each LED chip, the face surface is a surface of the each LED chip facing a drive backplane when the each LED chip is fixed to the drive backplane, and the face surface of the each LED chip is away from the carrier substrate. After the carrier substrate is aligned with the patterned substrate, at least part of the each LED chip is placed in the each through hole until the each bonding pad is bonded to a bottom of the each groove. After the carrier substrate is removed, a patterned support layer is disposed on a surface of the patterned substrate away from the temporary base plate, the patterned support layer is attached to the patterned substrate and the each LED chip, and the patterned support layer is hollow at a position opposite to the back surface of the each LED chip. The temporary base plate and bonding pads are removed to prepare the LED chip assembly.

In a third aspect, a preparing method of a display panel is further provided in the present disclosure. The preparing method includes the following. A drive backplane and a LED chip assembly are provided. The LED chip assembly includes a patterned substrate, a patterned support layer, and multiple LED chips. The patterned substrate defines multiple through holes. The patterned support layer is disposed on a surface of the patterned substrate and attached to the patterned substrate. Each LED chip at least partially extends into each through hole, the each LED chip is partially embedded in the patterned support layer, and the each LED chip has a face surface away from the patterned support layer. The patterned support layer defines a hollow structure which is at a position opposite to a back surface of the each LED chip and is for an operation body to extend into the hollow structure and touch the each LED chip, to apply a pressure to the each LED chip to make the each LED chip fall off the patterned support layer and out of the each through hole. When the each LED chip is fixed to the drive backplane, the face surface is a surface of the each LED chip facing the drive backplane and the back surface is a surface of the each LED chip away from the drive backplane. The drive backplane is aligned with the LED chip assembly, and the face surface of the each LED chip faces each chip reception area of the drive backplane. The operation body is controlled to extend into the hollow structure of the patterned support layer to abut against the back surface of the each LED chip, and the pressure is applied to the each LED chip until the each LED chip falls onto the each chip reception area. LED chips on chip reception areas are bonded to the drive backplane to prepare the display panel.

### BRIEF DESCRIPTION OF THE DRAWINGS

FIG. 1 is a schematic structural diagram of a light-emitting diode (LED) chip assembly provided in an optional implementation of the present disclosure.

FIG. 2 is a schematic top diagram of a patterned substrate provided in an optional implementation of the present disclosure.

FIG. 3 is a schematic diagram of using an operation body to lift off a LED chip from a LED chip assembly illustrated in an optional implementation of the present disclosure.

FIG. 4 is a schematic diagram of alignment of a LED chip assembly and a drive backplane illustrated in an optional implementation of the present disclosure.

FIG. 5 is a schematic diagram of alignment of another LED chip assembly and a drive backplane illustrated in an optional implementation of the present disclosure.

FIG. 6 is a schematic diagram of a positional relationship between a patterned support layer and LED chips illustrated in an optional implementation of the present disclosure.

FIG. 7 is a schematic diagram of another positional relationship between a patterned support layer and LED chips illustrated in an optional implementation of the present disclosure.

FIG. 8 is a schematic flowchart of a preparing method of a display panel provided in an optional implementation of the present disclosure.

FIG. 9 is a schematic diagram of process-state changes of preparation of a display panel provided in an optional implementation of the present disclosure.

FIG. 10 is a schematic flowchart of a preparing method of a LED chip assembly provided in another optional implementation of the present disclosure.

FIG. 11 is a schematic diagram of process-state changes of preparation of a LED chip assembly provided in another optional implementation of the present disclosure.

FIG. 12 is a schematic diagram of process-state changes of a temporary transfer substrate provided in another optional implementation of the present disclosure.

FIG. 13 is a schematic top diagram of a LED chip assembly provided in another optional implementation of the present disclosure.

FIG. 14 is a schematic top diagram of a LED chip assembly provided in yet another optional implementation of the present disclosure.

FIG. 15 is a schematic flowchart of a preparing method of a display panel provided in another optional implementation of the present disclosure.

FIG. 16 is a schematic diagram of process-state changes of preparation of a display panel provided in another optional implementation of the present disclosure.

FIG. 17 is a schematic diagram of process-state changes of preparation of LED chips provided in another optional implementation of the present disclosure.

Reference signs in the accompanying drawings are illustrated as follows:

10—LED chip assembly; 11—patterned substrate; 110—through hole; 12—patterned support layer; 120—operation hole; 13—LED chip; 30—LED chip assembly; 31—drive backplane; 32—bonded LED chip; 61—LED chip assembly; 62—drive backplane; 63—operaion body; 620—chip reception area; 81—carrier substrate; 82—temporary transfer substrate; 820—groove; 821—temporary base plate; 822—bonding layer; 823—bonding pad; 1201—growth base plate; 1202—epitaxial layer; 1203—indium tin oxide (ITO) pattern; 1204—distributed Bragg reflector (DBR) pattern; 1205—chip electrode; 1206—LED chip; 1207—temporary base plate; 1208—patterned substrate; 1209—through hole; 1210—benzocyclobutene (BCB) bonding adhesive layer; 1211—BCB bonding pad; 1212—silicon dioxide (SiO₂) layer; 1213—operation hole; 1214—LED chip assembly; 1215—drive backplane; 1216—ejector pin.

### DETAILED DESCRIPTION

In order to facilitate understanding of the present disclosure, a comprehensive description will be given below with reference to relevant accompanying drawings. The accompanying drawings illustrate some exemplary implementations of the present disclosure. However, the present disclosure can be implemented in many different forms and is not limited to the implementations described herein. On the contrary, these implementations are provided for a more thorough and comprehensive understanding of the present disclosure.

Unless otherwise defined, all technical and scientific terms used herein have the same meaning as commonly understood by those skilled in the art of the present disclosure. The terms used herein in the specification of the present disclosure are for the purpose of describing specific implementations only and are not intended to limit the present disclosure.

A micro light-emitting diode (Micro-LED) technology refers to a LED array with a micro size and integrated with high density on a drive backplane, which reduces displayed pixels from a millimeter level to a micrometer level. Compared with a traditional display technology, the Micro-LED has obvious advantages, and the Micro-LED has characteristics of high brightness, high efficiency, high reliability, and fast response time. In addition, electroluminescence, a small size, and other characteristics also make the Micro-LED more widely used.

However, due to lack of an excellent scheme for transferring Micro-LED chips to the drive backplane, production efficiency of a display panel is seriously affected and development of the Micro-LED technology is seriously restricted.

Based on this, the present disclosure hopes to provide a solution to the above technical problems, details of which will be expounded in subsequent implementations.

In an optional implementation of the present disclosure, a LED chip assembly is provided in the implementation first, and reference can be made to FIG. 1, which is a schematic structural diagram of a LED chip assembly 10. The LED chip assembly 10 includes a patterned substrate 11, a patterned support layer 12, and multiple LED chips 13.

In the implementation, each LED chip 13 may be the above Micro-LED chip, a Min-LED chip, or a LED chip with a larger size. In some examples of the implementation, the each LED chip 13 may also be an organic light-emitting diode (OLED) chip. In addition, a structural type and a color type of the each LED chip 13 are also not limited in the implementation. The each LED chip 13 may have a flip-chip structure, a face-up structure, a vertical structure, or a horizontal structure. The LED chip 13 may be a three-primary-colors (red, green, and blue) chip, or a LED chip of a color other than three primary colors.

Due to different settings of light-emitting surfaces and chip electrodes of LED chips of different structural types, an orientation of LED chips of the same structural feature is difficult to represent orientations of LED chips of different types. Therefore, in order to facilitate a later introduction of setting of the each LED chip 13 in the LED chip assembly 10, in the implementation, a “face surface” and a “back surface” of the each LED chip 13 are defined according to an orientation when the each LED chip 13 is fixed to the drive backplane. The face surface refers to a surface of the each LED chip 13 facing the drive backplane after the each LED chip 13 is bonded to the drive backplane, while the back surface refers to a surface of the each LED chip 13 away from the drive backplane after the each LED chip 13 is bonded to the drive backplane, that is, the surface of the each LED chip 13 opposite to the face surface. For example, a face surface of a LED chip with a flip-chip structure is a surface where chip electrodes are located, while a back surface is a main light-emitting surface of the LED chip with the flip-chip structure. However, in a LED chip with a face-up structure, a back surface of the LED chip with the face-up structure is a surface where chip electrodes are located, while a face surface is a surface opposite to the surface where the chip electrodes are located.

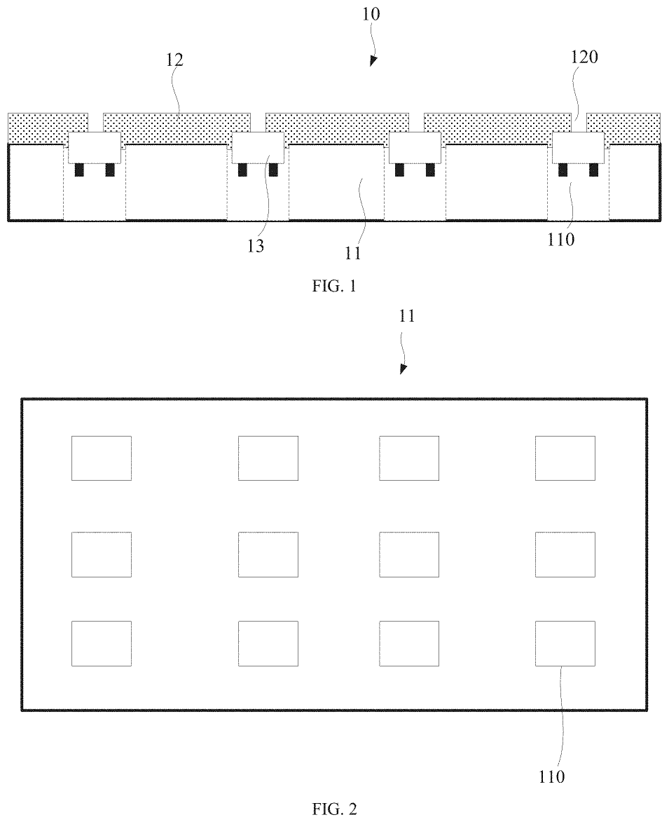

A patterned substrate 11 defines multiple through holes 110, and there is no doubt that each through hole 110 is a hole penetrating through upper and lower surfaces of the patterned substrate 11. Reference can be made to FIG. 2, which is a schematic top diagram of the patterned substrate 11. The multiple through holes 110 are arranged in an array on the patterned substrate 11, but it can be understood by those skilled in the art that in other examples, arrangement of through holes 110 may also adopt other schemes. However, since the each LED chip 13 will be supported in the each through hole 110, the arrangement of the through holes 110 on the patterned substrate 11 will affect arrangement of LED chips 13, while usually, the LED chips 13 in the LED chip assembly 10 will be directly transferred to the drive backplane. Therefore, in some examples, the arrangement of the through holes 110 on the patterned substrate 11 will follow arrangement of chip reception areas on the drive backplane. In addition, since the LED chips 13 in the LED chip assembly 10 are directly transferred from a carrier substrate (e.g., a growth substrate), the arrangement of the through holes 110 on the patterned substrate 11 will also follow arrangement of the LED chips 13 on the carrier substrate. In addition, the each through hole 110 in FIG. 2 has a rectangular cross section, but a shape of the each through hole 110 is not limited in the implementation. For example, the cross section of the each through hole 110 may also be a circular, an ellipse, a parallelogram, etc., as long as the each through hole 110 can make the each LED chip 13 pass from one side to another side in a posture of the face surface being parallel to a flat surface of the patterned substrate 11.

It can be understood that the patterned substrate 11 has a certain thickness, therefore, the each through hole 110 is actually equivalent to a channel for the each LED chip 13 to pass through. When the each LED chip 13 passes through the channel, a size of a cross section of the each through hole 110 determines a maximum movable range of the each LED chip 13 in a direction parallel to the patterned substrate 11. In the implementation, in order to prevent the each LED chip 13 from having a large positional shift and turnover during passing through the each through hole 110, the cross section of the each through hole 110 will be made relatively small. For example, in some examples of the implementation, the cross section of the each through hole 110 is only slightly larger than a cross section of the each LED chip 13.

On one hand, the patterned support layer 12 is attached to the patterned substrate 11, on the other hand, the patterned support layer 12 is also attached to the each LED chip 13, such that part of the each LED chip 13 is embedded into the patterned support layer 12, and another side of the each LED chip 13 can also be suspended in the each through hole 110 without any support, as illustrated in FIG. 1. In the implementation, the patterned support layer 12 is disposed on a surface of the patterned substrate 11, and the surface is a surface where the back surface of the each LED chip 13 is located. In other words, the patterned support layer 12 is disposed at a side where the back surface of the each LED chip 13 is located, and the face surface of the each LED chip 13 is away from the patterned support layer 12.

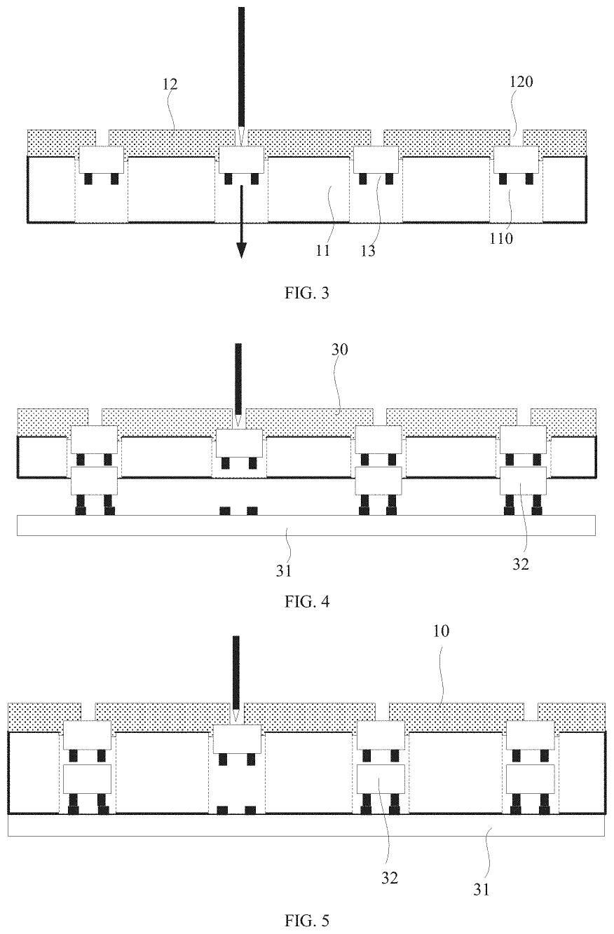

In the implementation, when the each LED chip 13 is suspended in the each through hole 110, at least part of the back surface of the each LED chip 13 is exposed beyond the patterned support layer 12. Therefore, the patterned support layer 12 defines a hollow structure at a position opposite to the back surface of the each LED chip 13. In this way, when the each LED chip 13 needs to be lifted off from the LED chip assembly 10, an operation body (such as an ejector pin, etc.) can extend into the hollow structure of the patterned support layer 12 and touch the back surface of the each LED chip 13. Therefore, when the operation body applies a pressure to the back surface of the each LED chip 13, the each LED chip 13 will move away from the patterned support layer 12, thereby falling off the patterned support layer 12 and leaving the LED chip assembly 10 through another side of the each through hole 110 (that is, a side opposite to a side where the patterned support layer 12 is located), as illustrated in FIG. 3.

In some examples of the implementation, hollow structures of the patterned support layer 12 at positions opposite to back surfaces of different LED chips 13 communicate with each other, that is, the hollow structures in the patterned support layer 12 where the different LED chips 13 communicate with each other. In other examples, hollow structures in the patterned support layer 12 where the each LED chip 13 is located are independent from each other. In some examples, each operation hole 120 is defined in the patterned support layer 12 at the position opposite to the back surface of the each LED chip 13. For example, in FIG. 1, the each operation hole 120 is accessible to the operation body such as the ejector pin, etc. Generally, a cross section of the each operation hole 120 is smaller than the back surface of the each LED chip. It can be understood that when the each operation hole 120 is smaller, the back surface of the each LED chip 13 is difficult to be contacted by an ordinary object through the each operation hole 120, so as to prevent the each LED chip 13 from falling off the LED chip assembly 10 due to extrusion of an external object during removal and transportation of the LED chip assembly 10. In the meantime, a size of the each operation hole 120 will not affect penetration of the operation body specially configured to lift off the each LED chip 13. Therefore, when the each LED chip 13 in the LED chip assembly 10 needs to be transferred to the drive backplane, the each LED chip 13 can be easily lifted off by means of a special operation body such as the ejector pin, etc., which is conductive to improving quality and reliability of the LED chip assembly 10. In other examples of the implementation, the cross section of the each operation hole 120 can also be greater than or equal to the back surface of the each LED chip 13. For example, in an example of the implementation, the patterned support layer 120 is attached to all of four side surfaces of the each LED chip 13, but is not attached to the back surface of the each LED chip 13, such that an area of the cross section of the each operation hole 120 is equal to an area of the back surface. In another example, the patterned support layer 120 is only attached to one or two side surfaces of the each LED chip 13, and certain gaps are defined between other two side surfaces of the each LED chip 13 and the patterned support layer 12. In this case, the area of the each operation hole 120 will be greater than the area of the back surface of the each LED chip 13.

A shape of the cross section of the each operation hole 120 includes, but is not limited to, a circle, an ellipse, a diamond, a triangle, a rectangle, etc. In addition, the shape of the cross section of the each operation hole 120 may also be a trapezium, a pentagram, or other regular or irregular shapes.

It can be understood that generally, when the LED chips are transferred to the drive backplane to prepare the display panel, all LED chips required on the drive backplane are not transferred in place at one time. For example, generally, LED chips of different colors will be transferred to the drive backplane in batches, and even LED chips of the same color are likely to be transferred in multiple batches. In this way, when some LED chips are transferred to the drive backplane, bonded LED chips have existed on the drive backplane. In addition, during LED chip repair, when a LED chip for repair is transferred to a position where the drive backplane needs to be repaired, the drive backplane has also been provided with abundant LED chips at other positions. In this case, if LED chips 13 are directly lifted off from the LED chip assembly to the drive backplane, some LED chips 13 will correspond to bonded LED chips 32 on the drive substrate after the LED chip assembly is aligned with the drive backplane. If a distance between a face surface of each LED chip 13 in a LED chip assembly 30 and a surface of the patterned substrate 11 facing the drive backplane 31 is too small, such as less than a height of each bonded LED chip 32 on the drive backplane 31, a distance between the LED chip assembly 30 and the drive backplane 31 will be interfered by the height of the each bonded LED chip 32, as illustrated in FIG. 4. In this case, the LED chip 13 lifted off from the LED chip assembly 30 cannot directly reach the drive backplane 31 after passing through the each through hole 110 in the patterned substrate 11, but needs to continue to fall for a distance. Within the distance, since the LED chip is not limited by the through hole 110, the LED chip 13 may shift, overturn, etc., which will affect the transfer yield of the LED chips 13 in LED chip assembly 30. Therefore, in order to avoid an effect of the height of the each bonded LED chip 32 on the drive backplane 31 on the distance between the LED chip assembly and the drive backplane, and improve the transfer yield of the LED chips in the LED chip assembly, in some LED chip assemblies provided in the implementation, such as in the LED chip assembly 10, the distance between the face surface of the each LED chip 13 and the surface of the patterned substrate 11 facing the drive backplane (i.e., a surface of the patterned substrate 11 away from the patterned support layer 12) is greater than the height of the each LED chip 13. In this way, even if bonded LED chips have existed on the drive backplane, free space in the each through hole 110 of the patterned substrate 11 is sufficient to accommodate the each bonded LED chip 32, as illustrated in FIG. 5.

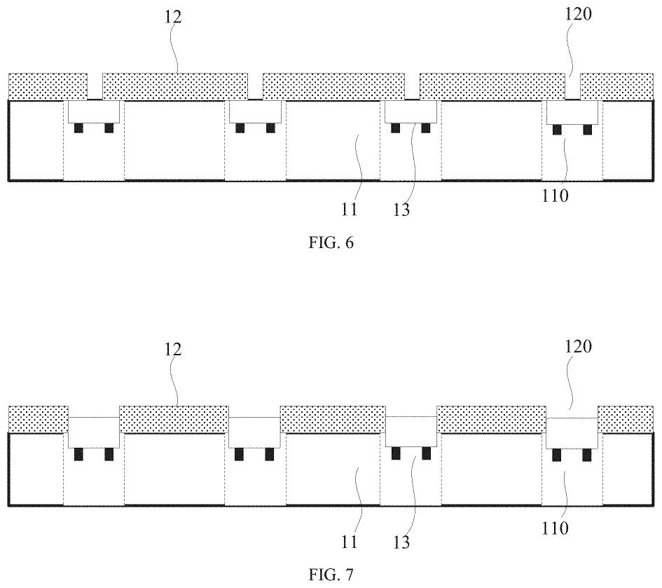

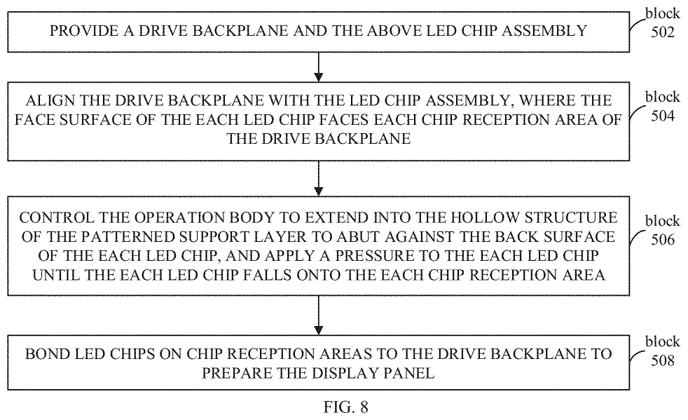

In some examples of the implementation, the patterned support layer 12 may only be attached to the back surface of the each LED chip 13, as illustrated in FIG. 6. In other examples, the patterned support layer 12 may only be attached to one or more side surface of the each LED chip 13, but not attached to the back surface of the each LED chip 13, as illustrated in FIG. 7. In addition, the patterned support layer 12 may be attached to both the back surface and side surfaces of the each LED chip 13, as illustrated in FIG. 1. In some examples of the implementation, the patterned support layer 12 may only be located at one side of the patterned substrate 11, but not be embedded in the through hole 110. In other examples, the patterned support layer 12 may also be attached to the surface of the patterned substrate 11 while being partially embedded in the each through hole 110. In some examples of the implementation, the back surface of the each LED chip 13 protrudes from the surface of the patterned substrate 11, as illustrated in FIG. 7 and FIG. 1. In other examples, the back surface of the each LED chip 13 may be flush with the surface of the patterned substrate 11, and reference can continue to be made to FIG. 6. In some implementations, the back surface of the each LED chip 13 may also be located in the each through hole 110.

Generally, the patterned support layer 12 does not have a deformation ability or has a poor deformation ability, which can avoid a problem that when the LED chip 13 tends to move away from the patterned support layer 12 due to the pressure of the operation body, the patterned support layer 12 continues to follow the LED chip 13 through deformation, resulting in a difficulty of separating the each LED chip 13 from the patterned support layer 12. A material with no deformation ability or the poor deformation ability is selected to form the patterned support layer 12, which can ensure that when the LED chip 13 tends to move away from the patterned support layer 12 due to the pressure of the operation body, the patterned support layer 12 is unable to be deformed and has to be separated from the each LED chip 13, such that the LED chip 13 can fall off the patterned support layer 12 cleanly. Therefore, in the implementation, the patterned support layer 12 may be made of a brittle material, and failure stress of the patterned support layer 12 is lower or much lower than a yield limit of the material. In some examples of the implementation, a material of the patterned support layer 12 includes, but is not limited to, silicon oxide (SiO₂), graphite, and metal (including metal with a high carbon content, such as pig iron, etc.).

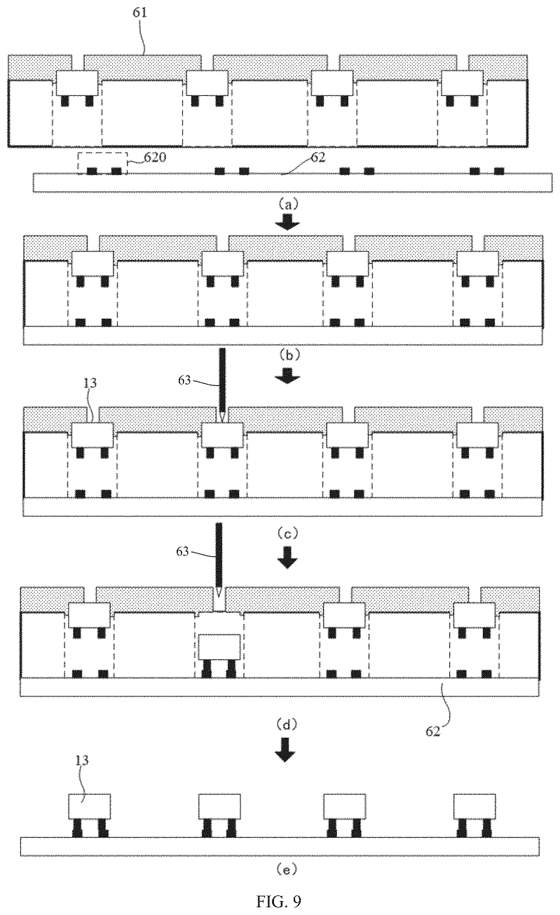

In order to make those skilled in the art clearer about an application process of lift off of the each LED chip in the LED chip assembly, a flow of preparation of the display panel by using the LED chip assembly is described below with reference to FIG. 8 and FIG. 9.

At block 502, a drive backplane and the above LED chip assembly are provided.

A LED chip assembly 61 provided in the implementation is the LED chip assembly 10 illustrated in FIG. 1, as illustrated in (a) in FIG. 9. However, it can be understood by those skilled in the art that the LED chip assembly 10 may also be other LED chip assemblies introduced in the above examples.

The drive backplane 62 includes multiple backplane electrodes on a chip carrier surface, two of these backplane electrodes are in a group to form a backplane electrode group, and an area where the backplane electrode group is located is one chip reception area 620, which needs to receive the LED chip 13 from the LED chip assembly 61.

At block 504, the drive backplane is aligned with the LED chip assembly, and the face surface of the each LED chip faces each chip reception area of the drive backplane.

After the drive backplane 62 and the LED chip assembly 61 are obtained, the drive backplane 62 can be aligned with the LED chip assembly 61. The each LED chip 13 needs to fall on the drive backplane 62 by gravity after the each LED chip 13 is pushed downwards to fall off the patterned support layer 12 by the operation body in a subsequent process, so when the drive backplane 62 is aligned with the LED chip assembly 61, the LED chip assembly 61 needs to be ensured to be on the top and the drive backplane 62 needs to ensure to be at the bottom, as illustrated in (b) of FIG. 9. In addition, the each LED chip 13 in the LED chip assembly 61 should be aligned with the each chip reception area 620 on the drive backplane 62. For example, the each LED chip 13 has a flip-chip structure, chip electrodes of the each LED chip 13 should be aligned with backplane electrodes of the drive backplane 62, which can ensure that the each LED chip 13 directly fall onto the each chip reception area 620 after the each LED chip 13 is separated from the patterned support layer 12, and ensure that the each LED chip 13 can be successfully bonded to the each chip reception area 620 on the basis of avoiding subsequent adjustment of a position of the each LED chip 13 on the drive backplane 62, thereby not only simplifying a process of transfer-and-bonding of the each LED chip 13, but also improving yield of transfer-and-bonding of the LED chips 13.

It can be understood that the each through hole 110 in the patterned substrate 11 can limit a shift of the each LED chip 13 in a horizontal direction and prevent turnover of the each LED chip 13 when the each LED chip 13 falls onto the drive backplane 62. However, after the each LED chip 13 passes through the each through hole 110, the shift and turnover may also occur. Therefore, in the implementation, after the LED chip assembly 61 is aligned with the drive backplane 62, a surface of the LED chip assembly 61 facing the drive backplane 62 can be directly attached to the drive backplane 62, such that the each LED chip 13 can fall on the drive backplane 62 without even passing through the each through hole 110, and no shift and turnover occur.

At block 506, the operation body is controlled to extend into the hollow structure of the patterned support layer to abut against the back surface of the each LED chip, and a pressure is applied to the each LED chip until the each LED chip falls onto the each chip reception area.

After a relative position of the drive backplane 62 and the LED chip assembly 61 is set, an operation body 63 can be controlled to extend into the hollow structure of the patterned support layer 12. There is no doubt that since the patterned support layer 12 is located on a side where the back surface of the each LED chip 13 is located, the operation body extending into the hollow structure can only abut against the back surface of the each LED chip 13, as illustrated in (c) of FIG. 9. After touching the back surface of the each LED chip 13, the operation body 63 can apply the pressure to the each LED chip 13 as illustrated in (d) of FIG. 9, such that the each LED chip 13 moves away from the patterned support layer 12 until the each LED chip 13 falls off the patterned support layer 12 to the each chip reception area 620 on the drive backplane 61, and the drive backplane 61 can provide the each LED chip 13 with a support force to balance gravity of the each LED chip 13.

At block 508, LED chips on chip reception areas are bonded to the drive backplane to prepare the display panel.

After the each LED chip 13 falls onto the each chip reception area 620 on the drive backplane 61, the each LED chip 13 can be bonded to the drive backplane 62, as illustrated in (e) of FIG. 9. It can be understood that bonding the each LED chip 13 to the drive backplane 62 not only includes fixing the each LED chip 13 to the drive backplane 62 to realize a physical connection between the each LED chip 13 and the drive backplane 62, but also includes realizing electrical coupling of the each LED chip 13 and the drive backplane 62. For example, the each LED chip 13 has the flip-chip structure. In the implementation, before the each LED chip 13 is lifted off from the LED chip assembly 61, a bonding material can be set on the backplane electrodes of the drive backplane 62 or the chip electrodes of the each LED chip 13 first, such that when the each LED chip 13 falls onto the drive backplane 62, bonding can be directly realized. Optionally, the bonding material includes, but is not limited to, solder, such as eutectic gold/tin (Au/Sn), tin solder, etc., and a conductive adhesive material, such as silver conductive adhesive, anisotropic conductive film (ACF), etc.

It can be understood that multiple LED chips 13 in the LED chip assembly 61 can be lifted off to the drive backplane 62 simultaneously. For example, multiple ejector pins push different LED chips downwards to fall, such that efficiency of transfer-and-bonding of the LED chips 13 can be improved. In addition, generally, some LED chips 13 bonded to the drive backplane 62 may be defective. Therefore, after the each LED chip 13 is bonded to the drive backplane 62, defective LED chips on the drive backplane 62 can be identified by detection and removed from the drive backplane 62, and then a LED chip assembly for repair is provided. The LED chip assembly for repair may also be the LED chip assembly 10 provided in the above examples. After the LED chip assembly for repair is aligned with the drive backplane 62, according to positions of the defective LED chips in the drive backplane 62, operation bodies are controlled to push LED chips which are for repair and at corresponding positions of the LED chip assembly for repair downwards. After the LED chips for repair are pushed downwards to the drive backplane 62, these LED chips can be bonded to the drive backplane 62 to realize LED chip repair. Defective LED chips may still exist after repair, so detection and repair need to be performed continually until no defective LED chips exist on the drive backplane 62. There is no doubt that during the LED chip repair, the operation body will not apply pressure to other LED chips in the LED chip assembly for repair except the LED chips for repair.

In a preparing method of the LED chip assembly and a preparing method of the display panel provided in the implementation, the each LED chip in the LED chip assembly is supported in the each through hole through the patterned support layer. Therefore, when the display panel is required to be prepared, the LED chip assembly is just required to be aligned with the drive backplane, and the each LED chip is pushed downwards through the operation body such as the ejector pin, etc., such that the each LED chip can fall onto the each chip reception area of the drive backplane. In addition, since limit and block of the each through hole can prevent the each LED chip from shifting and overturning in the process of transfer of the each LED chip to the drive backplane, not only can the transfer efficiency of the LED chips be improved, but also the transfer yield can be increased and preparation costs of the display panel can be reduced.

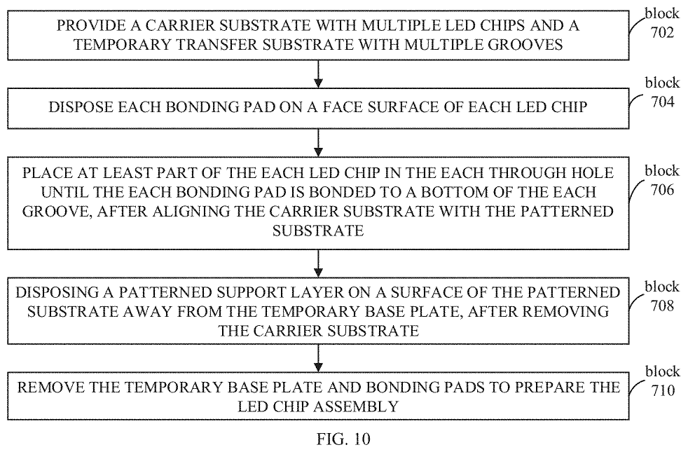

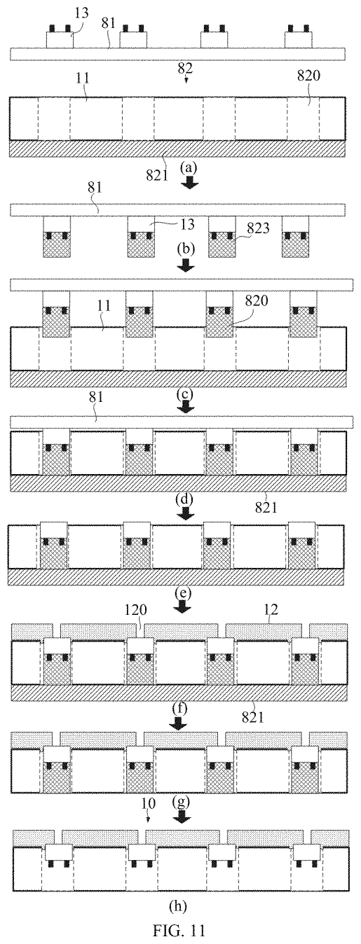

In another optional implementation of the present disclosure, a preparing method of the above LED chip assembly is provided in the implementation, and reference can be made to FIG. 10 and FIG. 11.

At block 702, a carrier substrate with multiple LED chips and a temporary transfer substrate with multiple grooves are provided.

Reference can be made to (a) in FIG. 11. In the implementation, a carrier substrate 81 is provided with multiple LED chips 13, and each LED chip 13 has a back surface facing the carrier substrate 81, that is, an orientation of the each LED chip 13 on the carrier substrate 81 is opposite to an orientation of the each LED chip 13 on drive backplane. For example, the each LED chip has a flip-chip structure, and when a flip LED chip is located on the drive backplane, chip electrodes of the flip LED chip faces the drive backplane, but when the flip LED chip is on the carrier substrate 81, the chip electrodes of the flip LED chip is away from the carrier substrate 81. In the implementation, the carrier substrate 81 may be a growth substrate of the each LED chip 13. For example, when the each LED chip 13 is a blue-light chip or a green-light chip, the carrier substrate 81 may be a sapphire substrate, a silicon substrate, or a gallium nitride (GaN) substrate where a blue-green epitaxial layer grows. In the implementation, the carrier substrate 81 is not excluded to be a substrate configured to carry the each LED chip 13 after growth of the each LED chip 13, that is, a transient substrate (also known as “temporary substrate”, “transfer substrate”, etc.).

A temporary transfer substrate 82 defines multiple grooves 820. Each groove 820 is actually a non-penetrating “blind hole” relative to the temporary transfer substrate 82. In the implementation, the temporary transfer substrate 82 includes a patterned substrate 11 with multiple through holes 110 and a temporary base plate 821 which are laminated. When an upper surface of the temporary base plate 821 is opposite to a lower surface of the patterned substrate 11, and no gap is between the upper surface of the temporary base plate 821 and the lower surface of the patterned substrate 11, a lower end of each through hole 110 will be sealed by a surface of the temporary base plate 821 to define the each groove 820. It should be understood that since the temporary transfer substrate 82 is formed by attachment of the temporary base plate 821 and the patterned substrate 11 which are independent from each other, the temporary base plate 821 and patterned substrate 11 which are in the temporary transfer substrate 82 can also be separated from each other when necessary.

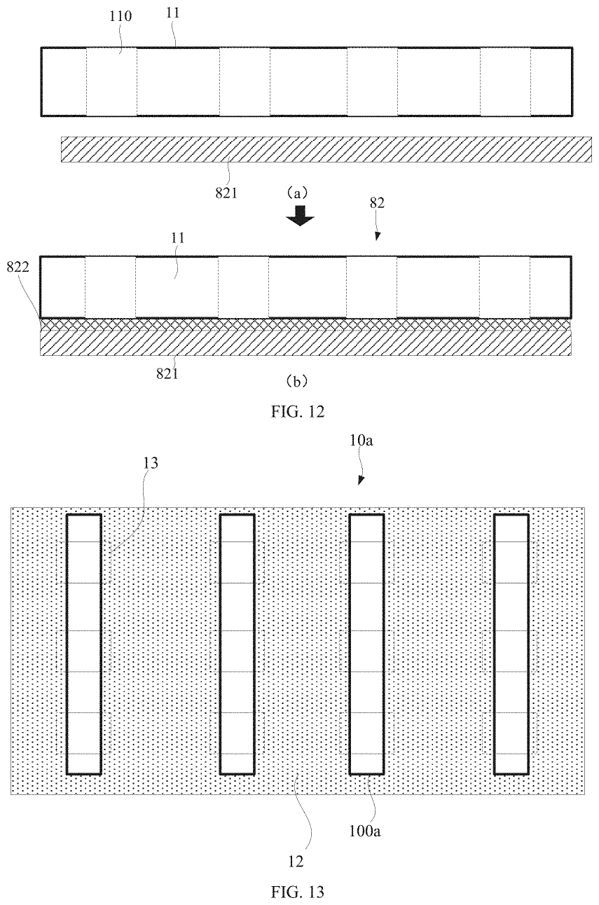

In some examples of the implementation, the temporary transfer substrate 82 further includes a bonding layer 822, and reference can be made to FIG. 12, which is a schematic diagram of process-state changes of preparation of a temporary transfer substrate 82. In (a) of FIG. 12, a temporary base plate 821 and a patterned substrate 11 are provided. Then, as illustrated in (b) of FIG. 12, after the temporary base plate 821 is aligned with the patterned substrate 11, the temporary base plate 821 is attached to the patterned substrate 11 through the bonding layer 822 between the temporary base plate 821 and the patterned substrate 11. In some examples of the implementation, the bonding layer 822 can be formed on other substrates in advance, and then transferred to a surface of the temporary base plate 821 facing the patterned substrate 11 or to a surface of the patterned substrate 11 facing the temporary base plate 821. In other examples, the bonding layer 822 can be temporarily formed on the surface of the temporary base plate 821 facing the patterned substrate 11 or on the surface of the patterned substrate 11 facing the temporary base plate 821.

In some examples of the implementation, the temporary base plate 821 and the patterned substrate 11 can be bonded together by bonding, so the bonding layer 822 may be a bonding adhesive layer, such as a benzocyclobutene (BCB) adhesive layer, a thermal release tape layer, etc. For example, the bonding adhesive layer is disposed on the surface of the temporary base plate 821 facing the patterned substrate 11, and the patterned substrate 11 is fixed to the temporary base plate 821 through the bonding adhesive layer. In some examples, a shape of a surface of the bonding adhesive layer is consistent with a shape of the surface of the patterned substrate 11, that is, the bonding adhesive layer defines each hollow structure at a position opposite to the each through hole 110 in the patterned substrate 11. In other examples, a shape of a surface of the bonding adhesive layer is consistent with a shape of the surface of the temporary base plate 821, and no hollow structure exists, as illustrated in (b) of FIG. 12. Therefore, the bonding adhesive layer is also exposed beyond at the bottom of the each groove 820. In other examples of the implementation, the temporary base plate 821 and the patterned substrate 11 can also be bonded by other methods, such as eutectic bonding, van der Waals force bonding, etc.

At block 704, each bonding pad is disposed on a face surface of each LED chip.

After the carrier substrate 81 with the multiple LED chips 13 is obtained, each bonding pad 823 can be disposed on a face surface of the each LED chip 13, as illustrated in (b) of FIG. 11. The each bonding pad 823 is mainly configured to bond the each LED chip 13 on the carrier substrate 81 to the bottom of the each groove 820 of the temporary transfer substrate 82, such that after the carrier substrate 81 is lifted off, the each LED chip 13 can be stabilized in the each groove 820 without support of the carrier substrate 81.

In some examples of the implementation, the each bonding pad may a sticky adhesive block, such as a BCB adhesive block, such that the each bonding pad 823 can bond and fix the each LED chip 13 at the bottom of the each groove 820. When the each bonding pad 823 is disposed, the liquid adhesive material can be coated on the face surface of the each LED chip 13. After the liquid adhesive material is cured, the each bonding pad 823 bonded to the face surface of the each LED chip 13 can be formed.

It can be understood that in some examples, the each groove 820 is provided with a bonding adhesive layer at the bottom of the each groove. Therefore, even if the each bonding pad 823 itself does not have stickiness, it is also feasible that as long as the each bonding pad 823 is attached to the each LED chip 13 and the each bonding pad 823 is in contact with the bonding adhesive layer at the bottom of the each groove 820 at the same time, because the bonding adhesive layer can be bonded to the each bonding pad 823, thus, the each LED chip 13 fixed to the each bonding pad 823 is fixed in the each groove 820.

At block 706, after the carrier substrate is aligned with the patterned substrate, at least part of the each LED chip is placed in the each through hole until the each bonding pad is bonded to a bottom of the each groove.

After the each bonding pad 823 is disposed on the face surface of the each LED chip 13, the carrier substrate 81 can be aligned with the patterned substrate 11, and the face surface of the each LED chip 13 faces a groove bottom of the each groove 820, as illustrated in (c) of FIG. 11. Then, the carrier substrate 81 can continue to move relative to the temporary transfer substrate 82 until the each bonding pad 823 is bonded to the bottom of the each groove 820, as illustrated in (d) of FIG. 11.

At block 708, after the carrier substrate is removed, a patterned support layer is disposed on a surface of the patterned substrate away from the temporary base plate.

After the each LED chip 13 on the carrier substrate 81 is bonded to the bottom of the each groove 820 through the each bonding pad 823, the carrier substrate 81 can be removed, as illustrated in (E) of FIG. 11. In some examples, the each LED chip 13 can be separated from and the carrier substrate 81 by laser lift off (LLO). For example, the each LED chip 13 is a GaN-based chip, and the carrier substrate 81 is the growth substrate of the each LED chip 13. When the carrier substrate 81 is lifted off, an interface between the carrier substrate 81 and the each LED chip 13 is irradiated by laser, causing a reaction of GaN→Ga+N₂ at the interface, thereby destroying attachment between the carrier substrate 81 and the each LED chip 13 and realizing removal of the carrier substrate 81.

After the carrier substrate 81 is removed, a patterned support layer 12 can be disposed on a surface of the patterned substrate 11 away from the temporary base plate 821, as illustrated in (f) of FIG. 11, that is, the patterned support layer 12 is disposed at a side where the back surface side of the each LED chip 13 is located. A disposed patterned support layer 12 is not only attached to the patterned substrate 11, but also is attached to the each LED chip 13, such that the patterned support layer 12 can fix a position of the each LED chip 13 in the each through hole 110 at the back surface of the each LED chip 13, so as to ensure that after support of the temporary base plate 821 is removed, the each LED chip 13 can continue to be kept in the same position in the each through hole 110 as before the temporary base plate 821 is removed.

As the name suggests, the patterned support layer 12 has a patterned layer structure. In the implementation, a main reason that the patterned layer structure is required is that at least part of the back surface of the each LED chip 13 facing the patterned support layer 12 is exposed beyond the patterned support layer 12, that is, the patterned support layer 12 is ensured to not cover all the back surface of the each LED chip 13, so as to ensure that an external operation body can directly touch the back surface of the each LED chip 13 in a subsequent process. Therefore, in the implementation, the patterned support layer 12 defines the hollow structure at the position opposite to the back surface of the each LED chip 13.

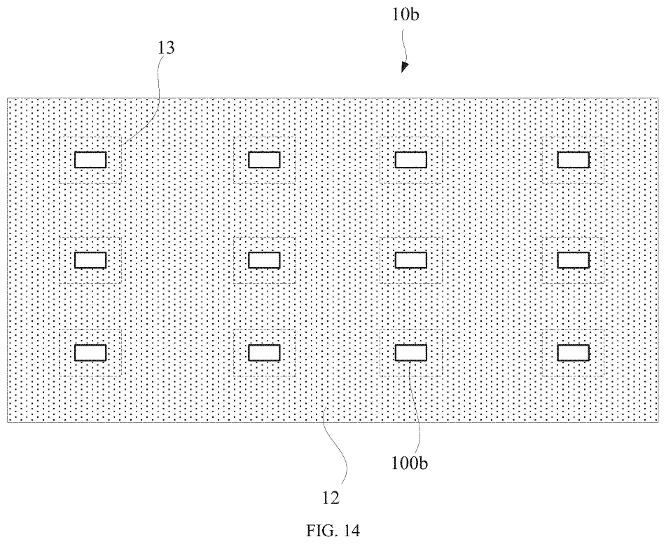

It can be seen from the introduction of the above implementations that hollow structures 100a in the patterned support layer 12 where the different LED chips 13 are located can communicate with each other. For example, reference can be made to FIG. 13, which is a schematic top diagram of a LED chip assembly 10a. In addition, in other examples, hollow structures 100b in the patterned support layer 12 where different LED chips 13 of the LED chip assembly are located can also be independent from each other, for example, a LED chip assembly 10b as illustrated in FIG. 14. When hollow structures are independent from each other, each operation hole 120 is defined at a position corresponding to a back surface of each LED chip 13 on the patterned support layer 12, and the each operation hole 120 is used for the operation body to extend into and apply the pressure to the each LED chip 13 to push the each LED chip 13 downwards.

In the implementation, the patterned support layer 12 is made of a brittle material, such as silicon oxide or metal. In other examples of the implementation, the patterned support layer 12 may be made of a relatively brittle adhesive material after curing. In some examples, a support material which forms the patterned support layer 12 can be disposed on the patterned substrate 11 by physical vapor deposition (PVD), chemical vapor deposition (CVD), vacuum evaporating (EV), etc.

It can be understood that in order to obtain the patterned layer structure, the support material can be deposited on a side of the patterned substrate 11 away from the temporary base plate 821 to form a complete support layer, then the support layer is patterned, and the support layer defines the hollow structure at the position opposite to the back surface of the each LED chip 13 by etching, so as to obtain the patterned support layer 12. This method of disposing the patterned support layer 12 is more suitable for a scenario of disposing the patterned support layer 12 with silicon oxide as the support material, because if the support layer is made of metal, a temperature of etching metal may exceed a temperature that an epitaxial layer of the each LED chip 13 can withstand during etching the support layer, resulting in damage of the each LED chip 13 during patterning the support layer.

In other examples of the implementation, when the patterned support layer 12 is disposed, a mask pattern can also be disposed first, the make pattern covers at least part of the back surface of the each LED chip, and then the support material is disposed through the mask pattern. With protection of the mask pattern, some areas of the back surface of the each LED chip 13 will not be covered by the support material, so the patterned support layer 12 can be obtained after the mask pattern is removed. This disposing scheme of the patterned support layer 12 is applicable to a scenario of using metal as the support material, because this disposing scheme can avoid a problem of damage of the each LED chip 13 caused by etching the support layer with a relatively high etching temperature after a metal material is deposited. As for a scenario with silicon oxide as the support material, this disposing scheme is usually not selected because the mask pattern is usually unable to withstand an excessive high deposition temperature of silicon oxide. However, it can be understood by those skilled in the art that currently common mask patterns are formed by a photoresist, but if other high-temperature resistant mask materials can be found, the patterned support layer 12 of a silicon oxide material can also be disposed in this way.

At block 710, the temporary base plate and bonding pads are removed to prepare the LED chip assembly.

After the patterned support layer 12 is disposed, a temporary base plate 821 and bonding pads 823 can be removed. Since the temporary base plate 821 and the patterned substrate 11 are bonded together, when the temporary base plate 821 is removed, a connection relationship between the temporary base plate 821 and the patterned substrate 11 needs to be destroyed first, such that the temporary base plate 821 can be separated from the patterned substrate 11. In some examples of the implementation, the temporary base plate 821 is bonded to the patterned substrate through the bonding adhesive layer (such as the thermal release tape layer or the BCB adhesive layer), such that a bonding ability of the bonding adhesive layer can be reduced by heating, and then the temporary base plate 821 can fall off, as illustrated in (g) of FIG. 11. The bonding pads 823 can be removed by etching, laser, etc., as illustrated in (h) of FIG. 11. After the temporary base plate 821 and bonding pads 823 are removed, the LED chip assembly 10 can be obtained.

It is can be understood that the patterned substrate 11 in the LED chip assembly 10 can be recycled. For example, when all LED chips 13 in the LED chip assembly 10 are lifted off, the patterned support layer 12 attached to the patterned substrate 11 can be removed, and then the patterned substrate 11 can continue to be used to prepare a new temporary transfer substrate, thereby forming a new LED chip assembly, which can reduce preparation costs of the LED chip assembly 10.

In the preparing method of the LED chip assembly provided in the implementation, the temporary transfer substrate with the multiple grooves is formed by the temporary base plate and the patterned substrate. In this case, the each bonding pad is disposed on the face surface of the each LED chip, and after the carrier substrate is aligned with the patterned substrate, the each LED chip is at least partially placed in the each through hole until the each bonding pad is bonded to the bottom of the each groove. Therefore, when the carrier substrate is lifted off, the each bonding pad can also support the each LED chip in the each through hole. In this case, the patterned support layer is disposed on the surface of the patterned substrate away from the temporary base plate. The patterned support layer will not only be attached to the patterned substrate, but also be attached to the each LED chip. Therefore, when the temporary transfer substrate and the each bonding pad are removed, the patterned support layer can provide force for the each LED chip to balance gravity of the each LED chip, such that the each LED chip can continue to be suspended in the each through hole. In the meanwhile, the patterned support layer is hollow at the position opposite to the back surface of the each LED chip, such that during the transfer of the each LED chip to the drive backplane, the external operation body can be ensured to extend into a hollow position and touch the each LED chip, to apply the pressure to the each LED chip to make the each LED chip fall off the patterned support layer under the pressure and out of the each through hole in the patterned substrate. Therefore, during the transfer of the each LED chip in the LED chip assembly to the drive backplane, as long as the LED chip assembly is aligned with the drive backplane and the face surface of the each LED chip faces the drive backplane, the each LED chip can be ensured to directly fall onto the each chip reception area of the drive backplane under the pressure of the operation body. The transfer process is simple and convenient. When the multiple operation bodies operate simultaneously, the multiple LED chips can be ensured to be transferred to the drive backplane simultaneously, such that the transfer efficiency of the multiple LED chips is improved. In addition, the process of the each LED chip falling is actually the process of the each LED chip passing through the each through hole, and when the each LED chip passes through the each through hole, the movement of the each LED chip in the horizontal direction will be limited by the side wall of the each through hole, such that the side wall of the each through hole can be used to limit the horizontal shift of the each LED chip during falling, the shift and turnover of the each LED chip can be reduced, the accuracy of the transfer position of the each LED chip can be improved, and the transfer yield of the LED chips can be improved.

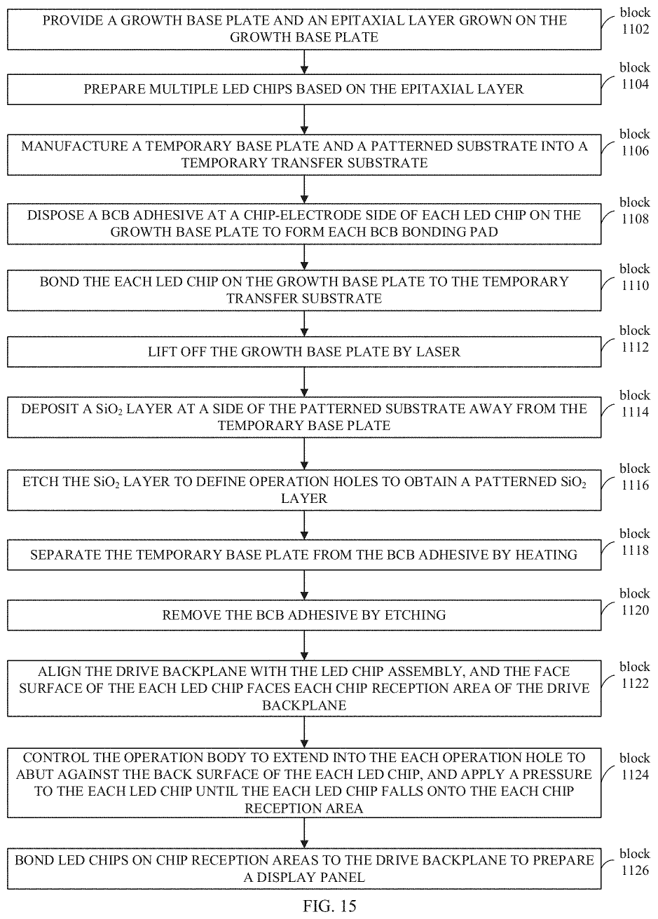

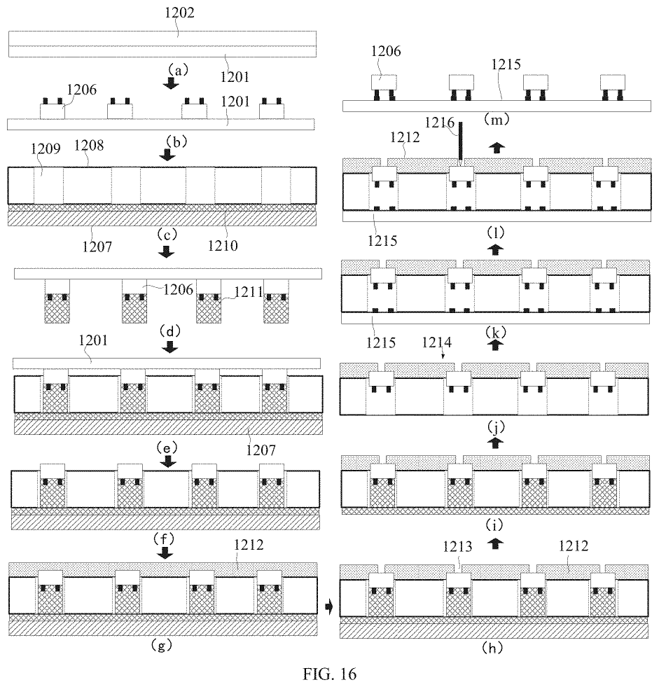

In yet another implementation of the present disclosure, in order to make those skilled in the art clearer about details and advantages of the above LED chip assembly and the preparing method thereof, and the preparing method of the display panel, the implementation will continue to elaborate preparation and application of the LED chip assembly in combination with examples, and reference can be made to FIG. 15 and FIG. 16.

At block 1102, a growth base plate and an epitaxial layer grown on the growth base plate are provided.

In the implementation, the epitaxial layer 1202 may be a GaN-based blue-green epitaxial layer, and a growth base plate 1201 is a sapphire substrate. As illustrated in (a) of FIG. 16, the epitaxial layer 1202 is deposited on the growth base plate 1201, and includes an N-type semiconductor layer (such as an N—GaN layer), an active layer, and a P-type semiconductor layer (such as a P—GaN layer) from bottom to top. It can be understood that the epitaxial layer 1202 includes but is not limited to these three layers, in addition, the epitaxial layer 1202 may also include at least one of a buffer layer, a stress-relief layer, an ohmic contact layer, and other layer structures.

At block 1104, multiple LED chips are prepared based on the epitaxial layer.

As illustrated in (b) of FIG. 16, after the growth base plate 1201 with the epitaxial layer 1202 is obtained, multiple LED chips 1206 are prepared based on the epitaxial layer 1202, and a process of preparing LED chips 1206 is elaborated below.

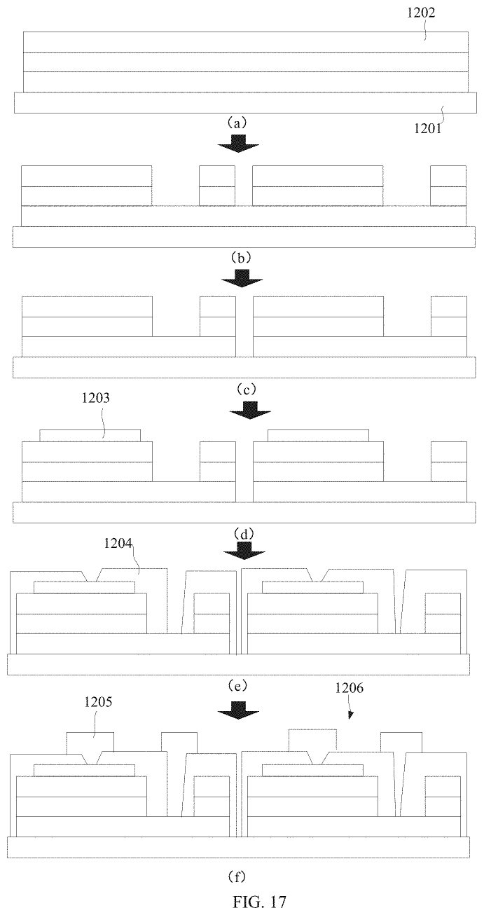

In (b) of FIG. 17, mesa etching is performed on the epitaxial layer 1202 provided in (a) of FIG. 17. An etching method is dry etching, and an etching gas may be at least one of boron trichloride (BCl₃) and chlorine (Cl₂).

In (c) of FIG. 17, trench etching continues to be performed on the epitaxial layer 1202 until the growth base plate 1201 is exposed. The etching method can also choose the dry etching, and the etching gas may be at least one of BCl₃ and Cl₂.

In (d) of FIG. 17, an indium tin oxide (ITO) layer with a thickness of 200-2000 Å can be sputtered on the epitaxial layer 1202, and then a mask pattern is formed on the ITO layer by using the photoresist, and an ITO pattern 1203 is obtained after performing wet etching on the ITO layer under cover of the mask pattern and photoresist stripping.

In (e) of FIG. 17, silicon oxide and silicon nitride are evaporated on the ITO pattern 1203 to form a distributed Bragg reflector (DBR), and the DBR has a thickness of 1˜4 μm; then, a mask pattern is formed on the DBR by using the photoresist, and subsequently the DBR is etched by the dry etching with at least one of carbon tetrafluoride (CF₄), oxygen (O₂), argon (Ar), and other etching gases, until the DBR is etched through. After the mask pattern is removed, a DBR pattern 1204 is obtained.

In (f) of FIG. 17, a negative photoresist is adopted to form a mask pattern on the DBR pattern 1204, and the mask pattern is used to dispose a PAD (i.e., a chip electrode) of a LED chip 1206, then an electrode layer is formed by evaporating electrode materials such as Fulin evaporation machine, and the electrode layer has a thickness of 1˜4 μm. After a blue film is lifted off and the photoresist is stripped, chip electrodes 1205 are obtained, and preparation of a LED chip 1206 is completed.

At block 1106, a temporary base plate and a patterned substrate are manufactured into a temporary transfer substrate.

In the implementation, each of the temporary base plate 1207 and the patterned substrate 1208 can be made of a sapphire substrate, a glass substrate, a silicon substrate, etc. The patterned substrate 1208 defines multiple through holes 1209 arranged in an array. Arrangement of through holes 1209 on the patterned substrate 1208 is the same as arrangement of the LED chips 1206 on the growth base plate 1201. Generally, each through hole 1209 has a cross section slightly larger than the each LED chip 1206, such as 2˜5 μm larger.

Reference can be made to (c) of FIG. 16, the patterned substrate 1208 may have a horizontal dimension identical to the temporary base plate 1207. For example, in an example, the temporary base plate 1207 and the patterned substrate 1208 each are 4 inches. The temporary base plate 1207 and the patterned substrate 1208 can be bonded together through a BCB bonding adhesive layer 1210. In the implementation, the BCB bonding adhesive layer 1210 can be coated on a surface of the temporary base plate 1207, and then the patterned substrate 1208 and the BCB bonding adhesive layer 1210 can be bonded together to realize bonding between the patterned substrate 1208 and the temporary base plate 1207. After the patterned substrate 1208 and the temporary base plate 1207 are bonded, the temporary transfer substrate is prepared, as illustrated in (c) of FIG. 16. As can be seen from (c) of FIG. 16, the each through hole 1209 becomes a groove after the patterned substrate 1208 is bonded to the temporary base plate 1207, and the BCB bonding adhesive layer 1210 is exposed beyond a bottom of the groove.

At block 1108, a BCB adhesive is disposed at a chip-electrode side of each LED chip on the growth base plate to form each BCB bonding pad.

After the each LED chip 1206 is prepared on the growth base plate 1201, the each bonding pad can be disposed on the face surface of the each LED chip 1206. Since the each LED chip 1206 in the implementation has a flip-chip structure, the each bonding pad is disposed on the chip-electric side of the each LED chip 1206. In addition, the each bonding pad in the implementation is formed by the BCB adhesive. Specifically, a liquid BCB adhesive can be coated on a side of the each LED chip away from the growth base plate 1201 to form the each BCB bonding pad 1211, as illustrated in (d) of FIG. 16.

It can be understood that a process of disposing the each BCB bonding pad 1211 on the face surface of each LED chip 1206 may be completed immediately after preparation of the each LED chip 1206, or may be executed after preparation of the temporary transfer substrate. It can be understood by those skilled in the art that no strict timing sequence exists between the process of disposing the each BCB bonding pad 1211 and a process of preparing the temporary transfer substrate.

At block 1110, the each LED chip on the growth base plate is bonded to the temporary transfer substrate.

Subsequently, the growth base plate 1201 can be aligned with the temporary transfer substrate, and the each LED chip can at least partially extend into the each through hole 1209 until the each BCB bonding pad 1211 and BCB bonding adhesive layer 1210 are bonded together, as illustrated in (e) of FIG. 16.

At block 1112, the growth base plate is lifted off by laser.

After the each LED chip 1206 is bonded to the groove, the growth base plate 1201 can be lifted off by laser, as illustrated in (f) of FIG. 16.

At block 1114, a SiO₂ layer is deposited at a side of the patterned substrate away from the temporary base plate.

After the growth base plate 1201 is lifted off, a surface of the patterned substrate 1208 away from the temporary base plate 1207 is exposed. In this case, a SiO₂ layer 1212 can be deposited by plasma enhanced chemical vapor deposition (PECVD), and the SiO₂ layer 1212 will be attached to both an exposed back surface of the each LED chip 1206 and the surface of the patterned substrate 1208 away from the temporary base plate 1207, as illustrated in (g) of FIG. 16. In some cases, the SiO₂ layer 1212 may also be embedded in the through holes 1209.

At block 1116, the SiO₂ layer 1212 is etched to define operation holes to obtain a patterned SiO₂ layer.

Since the SiO₂ layer 1212 disposed in (g) of FIG. 16 completely covers the surface of the patterned substrate 1208 away from the temporary base plate 1207, the back surface of the each LED chip 1206 is also all under the SiO₂ layer 1212. In order to expose at least part of the back surface of the each LED chip 1206, the SiO₂ layer 1212 will be etched in the implementation, so as to define each operation hole 1213 at a position opposite to the back surface of the each LED chip 1206, as illustrated in (h) of FIG. 16. An aperture of the each operation hole 1213 is usually small, but can be passed by the operation body, such as the ejector pin. The SiO₂ layer 1212 can be etched by dry etching, and etching gases include, but are not limited to, silane and laughing gas (i.e., nitrous oxide).

It can be understood that in other examples of the implementations, a metal layer can also be adopted to replace the SiO₂ layer 1212. However, if a metal layer is disposed, a mask pattern should be disposed before a metal material is deposited to avoid etching after arrangement of the metal layer.

At block 1118, the temporary base plate is separated from the BCB adhesive by heating.

After the patterned SiO₂ layer 1212 is disposed, the temporary base plate 1027 can be lifted off. In the implementation, an adhesive force of the BCB adhesive can be reduced by heating, and then the temporary base plate 1207 can be separated from the BCB adhesive layer, as illustrated in (i) of FIG. 16.

At block 1120, the BCB adhesive is removed by etching.

In the implementation, the BCB adhesive attached to the patterned substrate 1208 and the LED chip 1206 is also to be removed. Optionally, the BCB adhesive can be removed by the dry etching, as illustrated in (j) of FIG. 16. After the BCB adhesive is removed, the LED chip assembly 1214 is prepared.

At block 1122, the drive backplane is aligned with the LED chip assembly, and the face surface of the each LED chip faces each chip reception area of the drive backplane.

After preparation of the LED chip assembly 1214, the LED chip assembly 1214 can be applied. The each LED chip 1206 can be quickly and accurately transferred to the drive backplane through a structure of the LED chip assembly 1214. Optionally, the drive backplane 1215 can be aligned with the LED chip assembly 1214, and the face surface of the each LED chip 1206 can be kept facing each chip reception area of the drive backplane, as illustrated in (k) of FIG. 16.

At block 1124, the operation body is controlled to extend into the each operation hole to abut against the back surface of the each LED chip, and a pressure is applied to the each LED chip until the each LED chip falls onto the each chip reception area.

Subsequently, the operation body, such as an injector pin 1216, extends into each operation hole 1213 to abut against the back surface of the each LED chip 1206, and apply pressure to the each LED chip 1206 until the each LED chip 1206 falls off the SiO₂ layer 1212 and falls onto the each chip reception area of the drive backplane 1215, as illustrated in (1) of FIG. 16.

It can be understood that in the each LED chip 1206 with the flip-clip structure, the back surface is likely to have an area greater than the face surface, so an epitaxial layer of the each LED chip 1206 is inverted-trapezoid. In this case, when the each LED chip 1206 falls off the SiO₂ layer 1212, the SiO₂ layer 1212 will fragment, and some fragmented SiO₂ layers 1212 will be attached to a LED chip 1206 and taken away by the LED chip 1206. However, because the SiO₂ layer can passivate the LED chip 1206, basically no negative impact will be on performance of the LED chip 1206.

At block 1126, LED chips on chip reception areas are bonded to the drive backplane to prepare a display panel.

After the each LED chip 1206 falls onto the drive backplane 1215, the chip electrodes of the each LED chip 1206 can be bonded to the backplane electrodes on the drive backplane 1215 to realize transfer of the each LED chip 1206, as illustrated in (m) of FIG. 16.

It can be understood that the LED chips 1206 transferred to the drive backplane 1215 may be chips with different colors, to facilitate preparation of a colorful display panel.

In the implementation, quick mass transfer of LED chips can be realized and transfer efficiency of the LED chips can be improved by the patterned substrate and the patterned support layer. In this case, the each through hole in the patterned substrate can prevent the each LED chip from shifting and overturning during the each LED chip falling onto the drive backplane, such that the transfer yield of the LED chips is improved. In addition, since the patterned substrate can be reused, the preparation costs of the display panel are reduced.

It should be understood that the application of the present disclosure is not limited to the above examples, and for those of ordinary skill in the art, improvements or modifications can be made according to the above descriptions, and all such improvements and modifications shall fall within the protection scope of the appended claims of the present disclosure.

What is claimed is:

1. A light-emitting diode (LED) chip assembly, comprising:
a patterned substrate defining a plurality of through holes;
a patterned support layer disposed on a surface of the patterned substrate and attached to the patterned substrate; and
a plurality of LED chips, wherein
each LED chip at least partially extends into each through hole, the each LED chip is partially embedded in the patterned support layer, and the each LED chip has a face surface away from the patterned support layer;
the patterned support layer defines a hollow structure which is at a position opposite to a back surface of the each LED chip and is for an operation body to extend into the hollow structure and touch the each LED chip, to apply a pressure to the each LED chip to make the each LED chip fall off the patterned support layer and out of the each through hole; and
the face surface is a surface of the each LED chip facing a drive backplane and the back surface is a surface of the each LED chip away from the drive backplane, when the each LED chip is fixed to the drive backplane.

2. The LED chip assembly of claim 1, wherein the patterned support layer defines each hollow operation hole at the position opposite to the back surface of the each LED chip.

3. The LED chip assembly of claim 2, wherein the each operation hole has a cross section smaller than the back surface of the each LED chip.

4. The LED chip assembly of claim 1, wherein the patterned support layer is made of a brittle material.

5. The LED chip assembly of claim 1, wherein the patterned support layer comprises either silicon oxide or metal.

6. The LED chip assembly of claim 1, wherein the plurality of through holes are arranged in an array on the patterned substrate.

7. The LED chip assembly of claim 1, wherein the back surface of the each LED chip protrudes from the surface of the patterned substrate.

8. The LED chip assembly of claim 7, wherein the patterned support layer is attached to both the back surface and side surfaces of the each LED chip.

9. The LED chip assembly of claim 1, wherein a distance between a surface of the patterned substrate away from the patterned support layer and the face surface of the each LED chip is greater than a height of the each LED chip.

10. A preparing method of a light-emitting diode (LED) chip assembly, for preparation of the LED chip assembly of claim 1, comprising:
providing a carrier substrate with a plurality of LED chips and a temporary transfer substrate with a plurality of grooves, wherein the temporary transfer substrate comprises a patterned substrate with a plurality of through holes and a temporary base plate which are laminated, and each groove is defined by each through hole;
disposing each bonding pad on a face surface of each LED chip, wherein the face surface is a surface of the each LED chip facing a drive backplane when the each LED chip is fixed to the drive backplane, and the face surface of the each LED chip is away from the carrier substrate;
placing at least part of the each LED chip in the each through hole until the each bonding pad is bonded to a bottom of the each groove, after aligning the carrier substrate with the patterned substrate;
disposing a patterned support layer on a surface of the patterned substrate away from the temporary base plate, after removing the carrier substrate, wherein the patterned support layer is attached to the patterned substrate and the each LED chip, and the patterned support layer is hollow at a position opposite to the back surface of the each LED chip; and
removing the temporary base plate and bonding pads to prepare the LED chip assembly.

11. The preparing method of the LED chip assembly of claim 10, wherein disposing the each bonding pad on the face surface of the each LED chip comprises:
coating a liquid adhesive material on the face surface of the each LED chip;
wherein the each bonding pad bonded to the face surface of the each LED chip is formed after the liquid adhesive material becomes solid.

12. The preparing method of the LED chip assembly of claim 11, wherein providing the temporary transfer substrate with the plurality of grooves comprises:
providing the temporary base plate and the patterned substrate; and
bonding the patterned substrate and the temporary base plate through a bonding layer between the patterned substrate and the temporary base plate, after aligning the patterned substrate with the temporary base plate.

13. The preparing method of the LED chip assembly of claim 12, wherein the bonding layer is a bonding adhesive layer without a hollow; and placing the at least part of the each LED chip in the each through hole until the each bonding pad is bonded to the bottom of the each groove comprises:
applying a pressure towards each other to at least one of the carrier substrate and the temporary base plate until the each bonding pad is bonded to the bonding adhesive layer at the bottom of the each groove.

14. The preparing method of the LED chip assembly of claim 13, wherein at least one of the each bonding pad and the bonding adhesive layer is made of benzocyclobutene (BCB) adhesive.

15. The preparing method of the LED chip assembly of claim 10, wherein disposing the patterned support layer on the surface of the patterned substrate away from the temporary base plate comprises:
disposing a mask pattern, wherein the mask pattern covers at least part of the back surface of the each LED chip;
depositing a support material through mask patterns to form the patterned support layer; and
removing the mask patterns.

16. The preparing method of the LED chip assembly of claim 15, wherein the support material comprises metal.

17. The preparing method of the LED chip assembly of claim 10, wherein disposing the patterned support layer on the surface of the patterned substrate away from the temporary base plate comprises:
depositing a support material at a side of the patterned substrate away from the temporary base plate to form a support layer; and
patterning the support layer to make the support layer hollow at the position opposite to the back surface of the each LED chip.

18. The preparing method of the LED chip assembly of claim 17, wherein the support material comprises silicon oxide.

19. A preparing method of a display panel, comprising:
providing a drive backplane and the LED chip assembly of claim 1;
aligning the drive backplane with the LED chip assembly, wherein the face surface of the each LED chip faces each chip reception area of the drive backplane;
controlling the operation body to extend into the hollow structure of the patterned support layer to abut against the back surface of the each LED chip, and applying a pressure to the each LED chip until the each LED chip falls onto the each chip reception area; and
bonding LED chips on chip reception areas to the drive backplane to prepare the display panel.

20. The preparing method of the display panel of claim 20 further comprising:
after bonding the each LED chip on the each chip reception area to the drive backplane,
removing a defective LED chip on the drive backplane;
aligning a LED chip assembly for repair with the drive backplane;
controlling the operation body to push a LED chip at a corresponding position of the LED chip assembly for repair downwards, according to a position of the defective LED chip at the drive backplane; and
bonding the LED chip falling on the drive backplane to the drive backplane to realize repair.
